(19) United States
(12) Patent Application Publication
(10) Pub. No.: US 2010/0248498 A1
(43) Pub. Date: Sep. 30, 2010

(54) MATERIAL STRIPPING IN SEMICONDUCTOR DEVICES BY EVAPORATION

(76) Inventors: Petra Hetzer, Dresden (DE); Matthias Schaller, Moritzburg (DE); Daniel Fischer, Dresden (DE)

Correspondence Address: WILLIAMS, MORGAN & AMERSON, 10333 RICHMOND, SUITE 1100, HOUSTON, TX, 77042, US

(21) Appl. No.: 12/750,042

(22) Filed: Mar. 30, 2010

(30) Foreign Application Priority Data
Mar. 31, 2009 (DE) 10 2009 015 712.3

(51) Int. Cl. H01L 21/263; B23K 26/36

(52) U.S. Cl. 438/795; 219/121.86; 257/E21.333

(57) ABSTRACT

A sacrificial material, such as resist material, polymer material, organic residues and the like, may be efficiently removed from a surface of a semiconductor device by evaporating the material under consideration, which may, for instance, be accomplished by energy deposition. For example, a laser beam may be scanned across the surface to be treated so as to evaporate the sacrificial material, such as resist material, while significantly reducing any negative effects on other materials such as dielectrics, metals, semiconductive materials and the like. Moreover, by selecting an appropriate scan regime, a locally selective removal of material may be accomplished in a highly efficient manner.

### BACKGROUND OF THE INVENTION

1. Field of the Invention

Generally, the present disclosure relates to the field of fabricating semiconductor devices by using lithography techniques on the basis of resist masks.

2. Description of the Related Art

Today's global market forces manufacturers of mass products to offer high quality devices at a low price. It is thus important to improve yield and process efficiency to minimize production costs. This holds especially true in the field of semiconductor fabrication, since, here, it is essential to combine cutting edge technology with volume production techniques. Integrated circuits are typically manufactured in automated or semi-automated facilities, by passing substrates comprising the devices through a large number of process and metrology steps to complete the devices. The number and the type of process steps and metrology steps a semiconductor device has to go through depends on the specifics of the semiconductor device to be fabricated. A usual process flow for an integrated circuit may include a plurality of photolithography steps to image a circuit pattern for a specific device layer into a resist layer, which is subsequently patterned to form a resist mask for further manufacturing processes in structuring the device layer under consideration by, for example, etch or implant processes and the like. Thus, layer after layer, a plurality of process steps are performed based on a specific lithographic mask set for the various layers of the specified device. For instance, a sophisticated CPU requires several hundred process steps, each of which has to be carried out within specified process margins so as to fulfill the specifications for the device under consideration.

After patterning a given device layer on the basis of, for instance, a resist material, the mask material has to be removed by applying plasma assisted removal processes, wet chemical processes and the like. For example, for forming an appropriate dopant profile of circuit elements, such as transistors and the like, ion implantation is a frequently used technique, in which a dopant species may be incorporated into specific device areas, while other areas may be covered by a resist mask. In other cases, resist materials, polymer materials and the like may frequently be used as an etch mask, wherein the reduced removal rate of the mask material may be taken advantage of in order to preferably remove material from exposed device areas, which may be accomplished on the basis of wet chemical etch recipes, plasma assisted etch recipes and the like. In particular, after performing corresponding etch processes, the etch mask, possibly in combination with additional residues, such as organic materials, etch byproducts and the like, may have to be removed prior to continuing the further processing. Thus, it is highly desirable that any removal processes, such as plasma assisted resist strip techniques, may efficiently act on the mask materials and other residues, however, without unduly affecting the remaining device features of the semiconductor device. For example, frequently, plasma assisted resist strip processes may be performed by exposing the semiconductor device to an appropriate process ambient that may be established on the basis of an appropriate species, such as oxygen and the like, possibly in combination with other reactive components, which may be supplied to the process ambient in a highly reactive manner, i.e., in the form of radicals, which may be generated by a plasma that may be established remote to the actual process ambient on the basis of well-established techniques, for instance using microwave or inductively coupled plasma generators and the like. With the ongoing shrinkage of feature sizes of sophisticated semiconductor devices, however, the influence of any processes for removing a sacrificial material, such as photoresist, polymer materials and the like, may increasingly affect other materials, such as metals, semiconductors, dielectric materials and the like, which may thus compromise overall device performance and process efficiency.

With reference to FIGS. 1a and 1b, a typical plasma assisted resist strip process may be described for removing an implantation mask used to provide sophisticated shallow dopant profiles of advanced field effect transistors. It should be appreciated, however, that the influence of a resist removal process on actual device features, as will be described with reference to FIGS. 1a and 1b, is of illustrative nature only and similar and additional effects may typically be encountered during the removal of any other sacrificial materials, such as etch masks, etch residues and the like, in particular when semiconductor devices including extremely scaled circuit elements are considered.

FIG. 1a schematically illustrates a cross-sectional view of a semiconductor device 100 during a manufacturing stage in which appropriate dopant profiles are to be selectively formed in active areas of transistor elements. The semiconductor device 100 comprises a substrate 101, which may represent any appropriate carrier material for forming therein or thereon respective circuit elements, such as transistors, capacitors and the like. For example, the substrate 101 may represent a silicon bulk substrate or a silicon-on-insulator (SOI) substrate, since most of the complex integrated circuits, such as CPUs, storage chips and the like, are, and will be in the foreseeable future, formed on the basis of silicon. The device 100 further comprises a semiconductor layer 102, which may represent a silicon layer and the like, in which isolation structures 103 may define a first device region 110 and a second device region 120. For example, the device regions 110, 120 may correspond to active areas of transistor elements to be formed in and above the first and second device regions 110, 120. In the manufacturing stage shown in FIG. 1a, gate electrodes 111, 121 may also be formed above the semiconductor layer 102 and may be separated therefrom by gate insulation layers 113 and 123, respectively. It should be appreciated that, in highly sophisticated semiconductor devices, the ongoing shrinkage of features sizes may demand a gate length, i.e., in FIG. 1a, the horizontal extension of the gate electrodes 111, 121, of 50 nm and significantly less, thereby also necessitating sophisticated dopant profiles in the first and second device regions 110, 120. The gate electrodes 111, 121 may have formed thereon a sidewall spacer structure 112, 122, which may act as an implantation mask for laterally profiling the dopant concentration to be formed in the semiconductor material of the first and second device regions 110, 120. Additionally, the semiconductor device 100 comprises a resist mask 104, which may cover the first device region 110 and expose the second device region 120 during an ion bombardment of an implantation process 105.

The semiconductor device 100 as shown in FIG. 1a may be formed on the basis of the following processes. After providing the substrate 101 having formed thereon the semiconductor layer 102, possibly in combination with a buried insulating layer (not shown) when an SOI configuration is considered, the first and second device regions 110, 120 may be defined by forming the isolation structures 103. For this purpose, well-established techniques may be used including photolithography, anisotropic etch, deposition and polishing techniques. Thereafter, an appropriate masking regime may be used in order to selectively cover the first and second device regions 110, 120 for obtaining an appropriate vertical dopant profile in order to establish the basic transistor characteristics, such as the conductivity type of the transistors under consideration, the threshold voltage thereof and the like. The corresponding implantation sequences may be performed on the basis of well-established process parameters, such as implantation energy, implantation dose and the like, wherein, however, typically, the required dopant concentrations may be significantly less compared to the dopant concentrations required during the formation of PN junctions in the device regions 110, 120. Hence, although the corresponding implantation process may have a significantly lower impact on the corresponding resist mask, nevertheless, sophisticated resist removal processes may be required which may have an effect on any components provided so far. For convenience, any such effects are not described here in detail since further pronounced influences may be described with reference to the removal of the resist mask 104 in a later manufacturing stage. It should be noted, however, that the negative effects of any resist removal processes may result in an even further increased accumulated effect after passing through a plurality of manufacturing stages, in which several resist removal processes have been performed.

Next, the gate insulation layers 113, 123 may be formed on the basis of well-established oxidation and/or deposition processes followed by the deposition and patterning of a gate electrode material in order to obtain the gate electrodes 111, 121 having the desired lateral and vertical dimensions. Thereafter, the sidewall spacer structures 112, 122 may be formed by well-established techniques, while, in other cases, any additional manufacturing steps may be performed, for instance for incorporating a strain-inducing semiconductor material in at least one of the regions 110, 120, if required. Also, in this case, one or more resist masks may have to be provided and may have to be removed on the basis of techniques as will be described later on in more detail. Next, the resist mask 104 is formed on the basis of photolithography techniques and subsequently the device 100 is subjected to the implantation process 105, which may be designed so as to obtain a shallow dopant profile 124, thereby providing, for instance, an extension region of a corresponding drain and source region still to be formed in a later manufacturing stage. For example, the extension regions 124 may require a moderately high dopant concentration, thereby necessitating a high implantation dose in order to obtain the desired high dopant concentration. Due to the very restricted average penetration depth and thus the restricted implantation energy, the ion bombardment may also cause significant damage on exposed surface portions of the resist mask 104 down to a restricted depth, thereby creating a “crust layer” 104A, which may comprise carbonized resist material resulting in significantly different mechanical and chemical characteristics compared to the basis resist material of the mask 104. For example, the crust layer 104A having a high density compared to the substantially non-implanted remaining material of the mask 104 may cause a significantly different behavior during well-established plasma-based resist removal processes, thereby typically requiring additional reactive components in order to first etch the crust layer 104A prior to completely removing the remaining material of the mask 104. The additional etch species may, in addition to any other radicals present in the corresponding process ambient, contribute to a further increased influence on the surface portions exposed to the process ambient, for instance in the form of semiconductor material, dielectric material and the like.

FIG. 1b schematically illustrates the semiconductor device 100 during a conventional resist strip process 106 in order to efficiently remove the resist mask 104. The process 106 is configured as a plasma process based on oxygen and a further reactive component, such as fluorine in the form of carbon hexafluorine, in order to etch through the crust layer 104A. During the exposure to the ambient of the process 106, including oxygen radicals and the fluorine radicals, exposed surface portions 125 within the second device region 120 may be damaged by the reactive components, which may finally result in a significant material removal. For instance, carbon fluorine is well known to remove silicon, silicon dioxide and the like during a corresponding plasma-based process, which may thus result in a significant amount of material loss in the exposed device areas. For example, a material loss of up to approximately 2 nm, as indicated by the dashed line, may occur during the process 106, which may not be acceptable for devices having critical feature sizes of 50 nm and less. In particular, the significant material loss of exposed device areas may not only result in a corresponding thickness variation, depending on the specific process conditions, but may also result in a significant loss of dopants, thereby directly influencing the transistor performance.

Since a moderately high number of corresponding resist removal processes may be required in the various manufacturing stages, for instance for forming the basic transistor configuration, providing metallization systems and the like, the accumulated effect of the resist removal processes may be difficult to be predicted and may finally result in a significant variability of device characteristics, which may not be compatible with the restrictive margins required in highly advanced device generations.

The present disclosure is directed to various methods and systems that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides techniques and systems in which the removal of sacrificial material, such as resist material, polymer material and other material residues, may be efficiently performed without unduly affecting underlying material of the semiconductor device under consideration. For this purpose, the sacrificial material may be efficiently removed on the basis of an energy deposition within the sacrificial material in order to initiate the evaporation thereof so that the volatile components of the evaporated material may be efficiently removed from the corresponding process ambient. The energy deposition within the sacrificial material may, in some illustrative aspects disclosed herein, be accomplished by using radiation and/or energetic particles, for instance in the form of electrons or ions, while the radiation may be provided in the form of electromagnetic radiation, for instance obtained by laser sources, flashlight sources, microwave sources and the like. By appropriately selecting the parameters of the energy deposition, for instance in the form of wavelength and intensity of electromagnetic radiation, the desired “response” of the sacrificial material may be obtained without unduly affecting other materials, such as metals, dielectric materials, semiconductors and the like. For example, organic materials such as photochemically sensitive materials, such as photoresist and the like, may become highly volatile within a temperature range which may not significantly affect other materials of the semiconductor device. Consequently, the actual removal of the sacrificial material may be initiated by the temperature driven reaction within the sacrificial material, substantially without exposing other materials to highly reactive components and radicals, as is typically the case in conventional resist removal processes. Furthermore, in some illustrative aspects disclosed herein, the energy for initiating the evaporation of the sacrificial material may be supplied in a local manner, for instance by scanning a radiation beam or a particle beam across a portion of the semiconductor device so that the material removal may be accomplished in a very spatially selective manner, which may provide enhanced process flexibility since any non-removed sacrificial material may be used during the further processing of the semiconductor device, for instance in the form of a mask material and the like. In still other illustrative embodiments, the removal of the volatile components may be enhanced, for instance by introducing a reactive component into the process ambient, wherein, however, the type of reactive components, the amount thereof and the like may be appropriately selected so as to interact with the volatile components, thereby reducing any effect on other exposed device regions since the actual removal process may not have to be initiated by the additional reactive components, contrary to conventional process techniques, as previously described.

One illustrative method disclosed herein relates to removing a sacrificial material from above a surface of a semiconductor device. The method comprises transferring energy into at least a portion of the sacrificial material within a process ambient so as to evaporate the at least a portion of the sacrificial material and release volatile components of the sacrificial material into the process ambient. Additionally the method comprises processing the volatile components in the process ambient.

A further illustrative method disclosed herein comprises performing a process on a semiconductor device by using an organic material as a mask. The method further comprises exposing at least a portion of the organic material to at least one of radiation and energetic particles so as to evaporate the at least a portion of the organic material.

One illustrative material removal system disclosed herein comprises a process chamber configured to establish a specified low pressure process ambient. The material removal system further comprises a substrate holder positioned in the process chamber and configured to receive and hold in place a substrate having formed thereon semiconductor devices and a material to be removed from the semiconductor devices. Additionally, the material removal system comprises an energy source positioned so as to transfer energy into the material to be removed in order to evaporate the material selectively to other materials of the semiconductor devices.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a conventional semiconductor device during a manufacturing process on the basis of a resist mask and a subsequent resist removal process using a plasma assisted process ambient, according to conventional strategies;

FIGS. 2a-2b schematically illustrate cross-sectional views of a semiconductor device during a manufacturing sequence for removing a sacrificial material, such as a resist mask, by using energy deposition in order to initiate evaporation of the sacrificial material, according to illustrative embodiments;

FIG. 2c schematically illustrates a semiconductor device during the removal of a sacrificial material on the basis of evaporation initiated by a scanning beam of radiation or particles, according to illustrative embodiments;

FIG. 2d schematically illustrates the semiconductor device during the removal of material by evaporation on the basis of a process ambient containing an additional reactive species for further processing any volatile components of the sacrificial material, according to illustrative embodiments;

FIGS. 2e-2g schematically illustrate cross-sectional views of the semiconductor device in which a sacrificial material, such as resist material, polymer materials and the like, may be removed in a locally selective manner in order to perform at least one further manufacturing process on the basis of a remaining portion of the sacrificial material, according to still further illustrative embodiments; and

FIG. 3 schematically illustrates a material removal system for removing sacrificial material of semiconductor devices on the basis of evaporation, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure addresses the problem of undue negative effects caused by the removal of sacrificial materials, such as resist materials, any other polymer materials, organic residues and the like, during the processing of sophisticated semiconductor devices. To this end, techniques and systems may be provided in which the sacrificial material may be evaporated, i.e., decomposed and converted into volatile components by depositing energy in the sacrificial material substantially without requiring reactive components for obtaining the volatile components of the sacrificial material. The energy deposition may, in some illustrative embodiments, be accomplished in a locally selective manner, for instance by providing a beam of radiation or energetic particles in a scanning mode on the basis of appropriate position information so that an interaction of the scanning beam may be restricted to certain device regions. For example, a mask material or any other sacrificial material, which is to be understood as a material of which at least a portion is to be removed prior to the further processing of the semiconductor device under consideration, may be provided in a locally selective manner and may, therefore, be removed in a selective manner without requiring the exposure of non-covered device regions to the scanning radiation or particle beam. In other cases, the locally selective manner may provide enhanced flexibility for using materials and designing the overall manufacturing sequence since at least a portion of the “sacrificial” material may be used during the further processing of the semiconductor device, for instance in the form of an etch mask, an implantation mask and the like. In still other illustrative embodiments, material may be deposited and a “sacrificial” portion thereof may be subsequently removed on the basis of the principles disclosed herein, while the remaining portion may act as a permanent material, thereby avoiding additional lithography processes which may result in a significantly enhanced overall manufacturing flow. For example, a fill material for cavities or recesses, for instance adjacent to metal lines in a metallization system, may be globally deposited and may be subsequently locally selectively removed in order to provide corresponding air gaps in specific device regions, without requiring additional lithography steps, as long as the spatial resolution of a scanning radiation beam or particle beam is compatible with the required spatial resolution of the various device regions under consideration.

In some illustrative embodiments disclosed herein, the energy deposition may be accomplished by using electromagnetic radiation, for instance in the form of a “light” or microwave radiation, thereby providing a high degree of flexibility in selecting an appropriate wavelength and intensity of the radiation. It should be appreciated in this context that the term “light” is to be understood as electromagnetic radiation including the wavelength range of approximately 25 μm to 100 nm, for which appropriate radiation sources, such as laser devices and the like, are readily available. Consequently, by selecting appropriate parameters for the radiation, such as wavelength and intensity, in combination with a desired exposure time, an efficient evaporation of a plurality of materials, such as resist materials or any other polymer materials or generally organic materials, may be accomplished without significantly affecting non-covered materials of the semiconductor device since the finally obtained temperatures at the surface area of the semiconductor device may substantially not result in a significant material modification. For example, the wavelength of the radiation may be appropriately selected such that a significantly increased degree of absorption may be achieved in the material to be removed compared to any other materials, such as dielectrics, metals, semiconductive materials and the like, thereby breaking chemical bonds in the material to be removed, which may finally result in the creation of volatile components which may then be readily processed within the process ambient, for instance by further decomposing and removing the components or by simply removing the volatile components and the like. Appropriate wavelength ranges and intensities, in combination with appropriate exposure times, may be readily determined on the basis of test runs in which a plurality of different parameter settings may be applied for depositing energy in a desired sacrificial material. Depending on the radiation source and the characteristics of the radiation wavelength, a more or less pronounced spatial selectivity may be achieved, if desired, for instance by using a laser source and using an appropriate beam shaping system so as to obtain the desired size of the laser spot. Consequently, if desired, a spatial resolution of a corresponding radiation beam of approximately 1 μm to several tens of micrometers may be achieved on the basis of available laser radiation sources. In some cases, a more global exposure to radiation may be applied, for instance on the basis of flashlight sources, microwave radiation sources and the like, if considered appropriate. For instance, microwave energy may be supplied to as to excite molecules within the sacrificial organic material, as long as any antenna effects within the semiconductor device may not have a negative influence on the further processing of the device and the finally obtained characteristics thereof.

In other illustrative embodiments, energetic particles, such as an electron beam or an ion beam, may be used for depositing energy in the sacrificial material, wherein, depending on the characteristics of a particle beam, if desired, an even further enhanced spatial resolution may be accomplished compared to a radiation having a wavelength of approximately 100 nm. Consequently, if an interaction of the energetic particle beam with other materials may be considered inappropriate, the corresponding beam may be substantially restricted to device areas covered by the sacrificial material, thereby also minimizing the degree of material modification caused by the energetic particles.

In other illustrative embodiments disclosed herein, the evaporation of a sacrificial material may be initiated in a more global manner, for instance by providing energy in a global way, for instance in the form of radiation or heat, which may be applied in a controlled manner so as to obtain the desired evaporation without unduly affecting other device materials. For example, a plurality of rapid “anneal” techniques may be used in which, however, the temperature may be selected so as to have an appropriate value, for instance in the range of approximately 300-500° C. or even higher, in order to appropriately initiate the evaporation of the sacrificial material while, on the other hand, the temperature is still low enough in order to cause a significant temperature induced modification in other materials. Hence, also in this case, the volatile components may be created without introducing any reactive components which may conventionally react with exposed surface areas of other materials, thereby causing significant modifications.

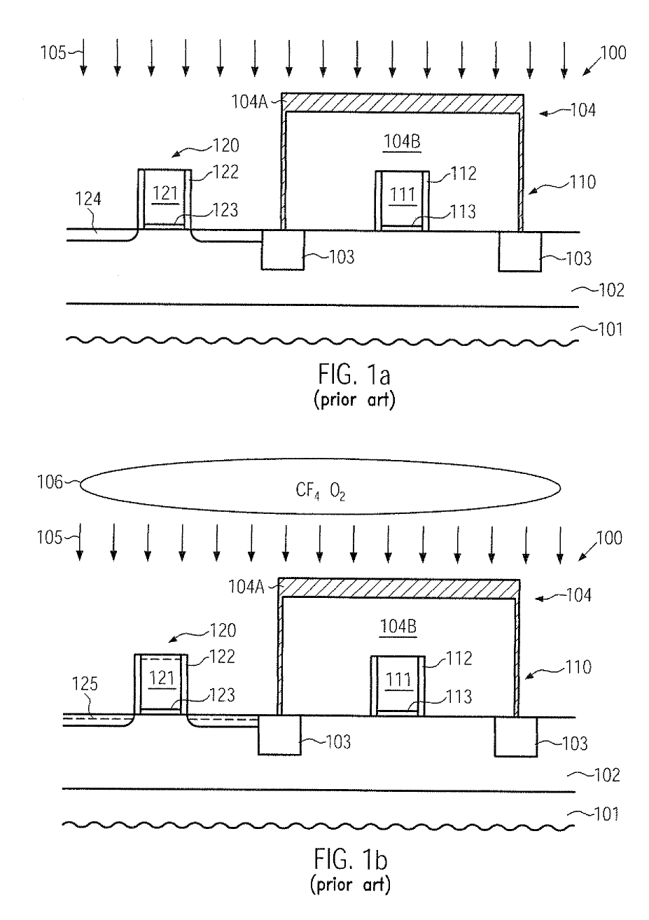

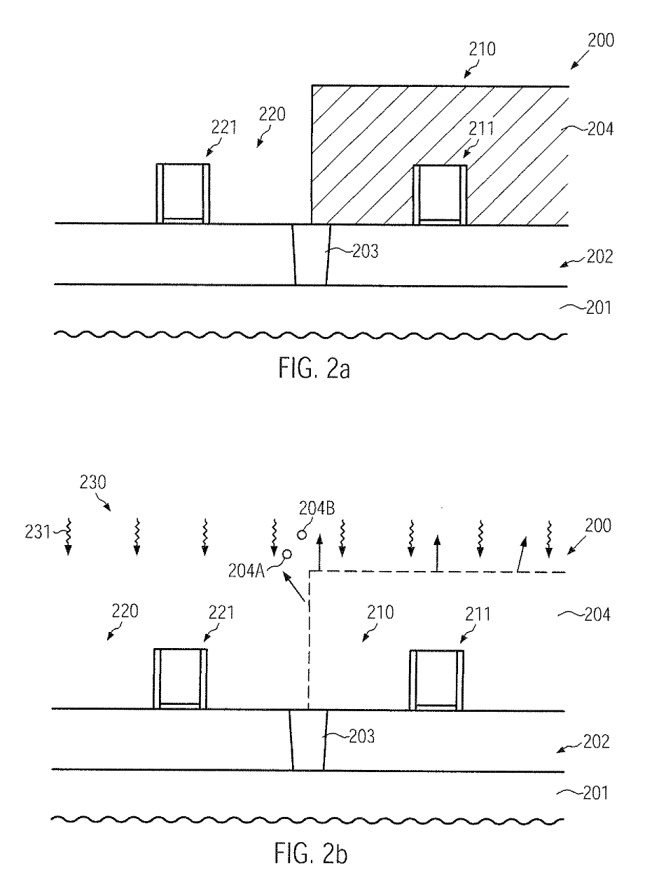

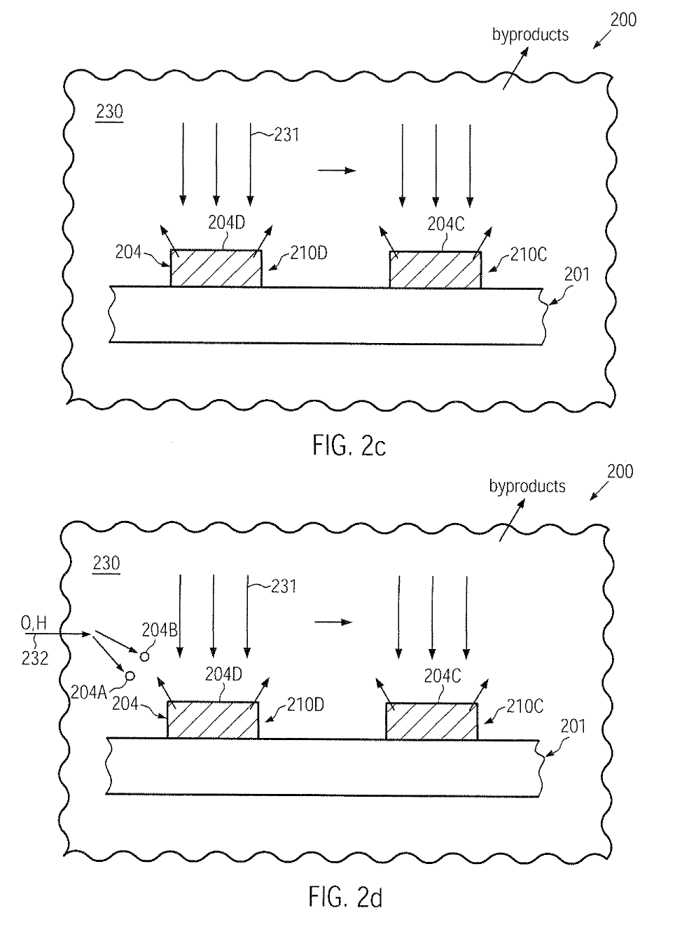

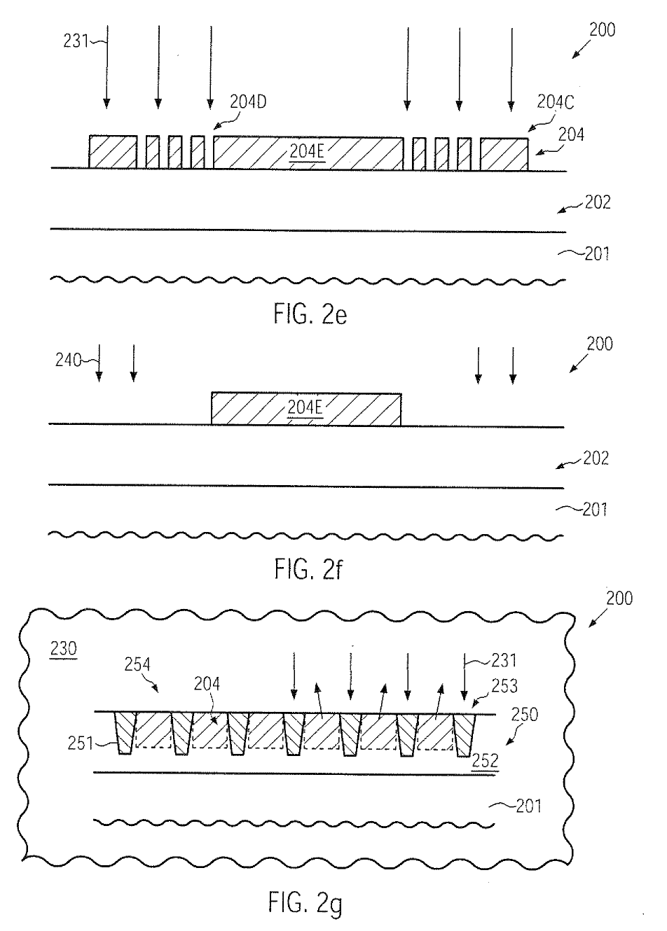

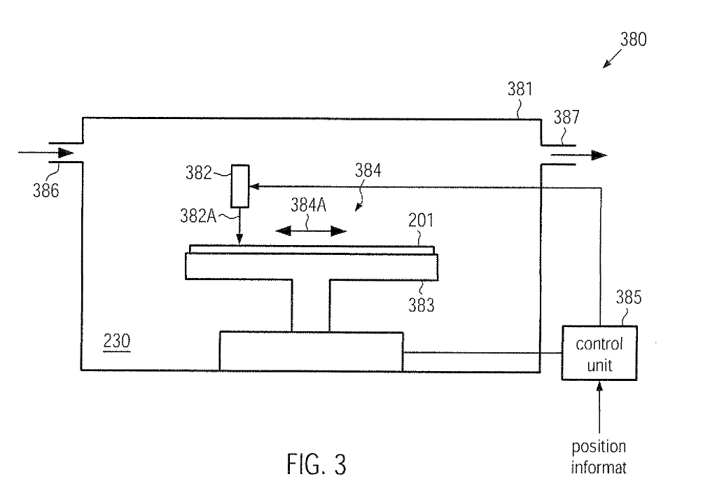

With reference to FIGS. 2a-2f and 3, further illustrative embodiments will now be described in more detail, wherein reference may also be made to FIGS. 1a-1b, if required.

FIG. 2a schematically illustrates a cross-sectional view of a semiconductor device 200 which may represent any microstructure device comprising at least some circuit elements, such as transistors and the like. The semiconductor device 200 may comprise a substrate 201 in combination with a semiconductor layer 202, such as a silicon-based layer, a silicon/germanium layer and the like. It should be appreciated that the semiconductor layer 202 may represent any appropriate semiconductor material which may be required for forming therein and thereabove respective circuit elements, such as transistors and the like. As previously indicated with reference to the semiconductor device 100, the substrate 201 in combination with the semiconductor layer 202 may define, at least locally, an SOI configuration if a buried insulating material is positioned between the substrate 201 and the semiconductor layer 202. In other cases, the substrate 201 may comprise a semiconductor material and the semiconductor layer 202 may be formed directly on the semiconductor material of the substrate 201, thereby forming a “bulk” configuration. In the manufacturing stage shown, the semiconductor device 200 may comprise device features 211, 221 which may represent components formed in or above a first device region 210 and a second device region 220, respectively. It should be appreciated that the device features 211, 221 may represent any appropriate components, such as a gate electrode structure and the like, as, for instance, previously explained with reference to the semiconductor device 100. In other cases, the first and second device regions 210, 220 may be provided in a manufacturing stage in which any further components are still to be formed, as is also previously discussed with reference to the device 100. For instance, an isolation structure 203 may separate the device regions 210, 220 in order to form therein corresponding transistor elements of reduced dimensions, as is also previously explained with reference to the semiconductor device 100. It should be appreciated, however, that the device features 211, 221, 203 are of illustrative nature only and the principles disclosed herein may be applied to the semiconductor device 200 at any other appropriate manufacturing stage in which the removal of a sacrificial material, such as a resist material and the like, may be required. In the embodiment shown, a sacrificial material 204, for instance in the form of a resist mask, may be provided so as to cover the first device region 210 and expose the second device region 220, which may, for instance, be required for performing an etch process, an implantation process and the like. For instance, as previously discussed, sophisticated implantation processes may typically be required for forming advanced field effect transistors requiring a shallow dopant profile. In other cases, etch processes may be performed, for instance for selectively providing cavities in the device region 220, which may be subsequently filled with an appropriate semiconductor alloy in order to enhance performance of field effect transistors by inducing an appropriate type and magnitude of strain.

The semiconductor device 200 may be formed on the basis of any appropriate process sequence, which may include manufacturing steps, as are also previously explained with reference to the semiconductor device 100, when the device regions 210, 220 and the corresponding device features 211, 221 represent components of field effect transistors, as previously explained. Consequently, after providing the sacrificial material 204 in the form of organic material, such as a resist material, i.e., a photochemically sensitive material or any other polymer material, a corresponding treatment, such as an implantation, an etch process and the like, may be applied.

FIG. 2b schematically illustrates the semiconductor device 200 when exposed to a process ambient 230 in which energy 231 is “deposited” in the material of the mask 204 in order to increasingly evaporate the material, thereby producing volatile components 204A, 204B which are thus released into the ambient 230. The energy 231 may be provided in the form of electromagnetic radiation, such as light radiation and microwave radiation, as previously explained, wherein a wavelength or wavelength range and an intensity may be appropriately selected so as to obtain a high absorption rate within the sacrificial material 204 without unduly affecting other device areas, such as the device region 220. For instance, laser radiation with a wavelength in the range of approximately 20 μm-100 nm may result in an efficient energy deposition within the mask 204, thereby obtaining moderately high temperatures at the surface of the device 200, which may thus result in an efficient evaporation and thus creation of the volatile components 204A, 204B. That is, due to the efficient absorption of energy, chemical bonds within the material 204 are broken and result in a release of the volatile components 204A, 204B without requiring additional chemically reactive components. On the other hand, the corresponding degree of energy absorption in the non-covered device region 220 may be significantly less or the resulting temperatures below a critical value so as to cause a significant material modification. For example, typically organic materials, such as resist materials, even if exposed to a preceding treatment such as implantation of low energetic ions and the like, as previously explained, may exhibit a significant evaporation rate with a surface temperature of approximately 300-500° C., which may substantially not result in a significant material modification in the device region 220. It should be appreciated that appropriate process parameters, for instance a wavelength or wavelength range and an intensity of the energy 231, if provided in the form of electromagnetic radiation, may readily be determined on the basis of test runs. For example, for a given type of material, an appropriate wavelength and energy density, i.e., energy per unit area, may be determined in combination with an appropriate exposure time, i.e., an appropriate power density, so as to obtain the desired evaporation effect. It should be noted in this respect that a plurality of laser sources are available in which the energy density and exposure time, i.e., power density, may be readily adjusted by controlling a spot size of the laser beam, controlling supply voltage and the like. For instance, a power density of approximately 1 W to several Watts per cm² may be applied in order to evaporate a plurality of organic materials, such as resist materials, polymer materials and the like, wherein an appropriate power density may be readily adjusted on the basis of an exposure time using an appropriate scan regime, as will be described later on in more detail.

In the embodiments shown in FIGS. 2a and 2b, the device regions 210, 220 may represent neighboring device regions which may both be exposed to the energy 231 since a spatial resolution of the energy 231 may not be sufficient so as to “distinguish” between the regions 210 and 220. In other illustrative embodiments, if an increased spatial resolution may be desirable, the energy 231 may be provided in the form of a beam including energetic particles, which are to be understood as particles having sufficient kinetic energy so as to be shaped by a beam-shaping system in order to provide the desired directionality and also to break up chemical bonds within the material 204 in order to generate the volatile components 204A, 204B. For instance, the energy 231 may be provided in the form of an electron beam or an ion beam, wherein a corresponding beam size may be adjusted in accordance with overall requirements. For instance, if a high spatial resolution may be required, the corresponding particle beam may provide a resolution of several nanometers, if required, while in other cases a more global exposure of the device 200 may be used. Thus, in this case, a highly local selectivity of the energy deposition may be achieved, if required, for instance, on the transistor level of sophisticated semiconductor devices, when a corresponding interaction of the energetic particles with the exposed portion 220 may not be considered inappropriate. In other cases, a spatial resolution based on electromagnetic radiation may be obtained, depending on the wavelength used, wherein any negative effects on non-covered circuit areas, such as the device region 220, may substantially not result in undue material modification.

FIG. 2c schematically illustrates the semiconductor device 200 exposed to the process ambient 230, wherein the energy 231 may be deposited in a locally selective manner, which is to be understood that the energy 231 may be provided in a locally restricted manner above the substrate 201 in accordance with the spatial resolution that is compatible with a corresponding scan regime and wavelength, as previously discussed. For instance, in the embodiment shown in FIG. 2c, a device region 210C and a device region 210D may be defined above the substrate 201 and may be covered by corresponding portions 204C, 204D, respectively, of the sacrificial material 204. For instance, the regions 210C, 210D may represent different device regions within a single die area of the substrate 201, which may have lateral dimensions of several tens of micrometers and more, depending on the overall device requirements. In other cases, the regions 210C, 210D may represent different die regions, which may require different treatments during the further processing. For example, the regions 210C, 210D may represent a test region and a product die region, respectively, or the regions 210C, 210D may represent product die regions requiring different characteristics and the like. In this case, the energy 231, for instance in the form of laser energy and the like, may be provided in a locally selective manner so as to heat one or both of the portions 204C, 204D substantially without affecting any other device areas above the substrate 201. For this purpose, the energy 231 may be laterally restricted to one or both of the portions 210C, 210D, for instance by using appropriate beam-shaping systems and scan systems if a corresponding beam size has a lateral size that is less than a lateral size of the regions 210C, 210D and the like. Upon exposure to the energy 231, the portion 204C and/or 204D may be evaporated in order to produce volatile components, which may then be efficiently removed from the ambient 230, as is also previously explained. Consequently, the overall process time for removing an unwanted portion of the sacrificial material 204 may be reduced since the treatment may be spatially restricted to those portions which have to actually be removed.

FIG. 2d schematically illustrates the semiconductor device 200 according to still further illustrative embodiments in which an additional reactive species 232 may be introduced into the process ambient 230 in order to initiate a reaction with the volatile components 204A, 204B. In some illustrative embodiments, components such as oxygen, nitrogen and the like may be introduced so as to preferably react with the volatile components 204A, 204B, for instance for further decomposing these components while maintaining a reaction rate with other exposed device areas at a low level. Consequently, a significantly reduced amount of reactive components may be added to the process ambient 230 compared to conventional strategies and also less aggressive components may be used since the chemical reaction may, contrary to conventional strategies, take place on the basis of the volatile components 204A, 204B, which have been released on the basis of the evaporation caused by the energy 231. Thus, contrary to conventional strategies, the reactive components 232 may not have to chemically react with the material 204 in order to generate any volatile components, thereby providing a significantly increased degree of flexibility in creating an appropriate process ambient so as to efficiently remove unwanted portions of the material 204 without significantly affecting other exposed device areas. The reactive components 232 may be provided in any appropriate form, for instance in the form of gases, treated gases including radicals, which may be generated on the basis of a remote plasma ambient, and the like.

FIG. 2e schematically illustrates the semiconductor device 200 according to further illustrative embodiments in which a sacrificial material, for instance in the form of a resist mask, may be locally selectively removed and the further processing may be continued on the basis of a remaining portion of the sacrificial material. As illustrated, the semiconductor device 200 may comprise the material 204 in the form of the portions 204C, 204D which may have to be removed on the basis of energy deposition and evaporation, as previously explained, while a further portion 204E may have to be maintained so as to be used during the further processing of the device 200. For this purpose, the energy 231 may be provided in a locally selective manner, for instance by using an appropriate scan regime, as will be described later on in more detail, during which exposure of the portion 204E may be avoided. It should be appreciated that the portions 204C, 204D may comprise a corresponding “fine structure,” which may be understood as any appropriate masking regime for exposing and covering dedicated minute device areas, such as specific transistor areas and the like, as previously explained with reference to the device regions 210, 220 (FIGS. 2a and 2b). Consequently, even if the spatial resolution capability of the corresponding radiation beam and scan regime for providing the energy 231 may not allow resolving the fine structure in the portions 204C, 204D, an efficient removal thereof may nevertheless be insured without unduly affecting any non-covered areas, as previously explained.

FIG. 2f schematically illustrates the semiconductor device 200 in a further advanced manufacturing stage in which the remaining portion 204E may be used during a further process step 240, in which a process result may be substantially restricted to areas not covered by the portion 204E. For instance, the manufacturing process 240 may represent an implantation process, for instance for introducing dopant species for bombarding covered material layers so as to obtain a certain degree modification and the like, wherein the ion blocking effect of the portion 204E may result in a local selectivity without requiring additional photolithography steps. For instance, certain device regions above the semiconductor layer 202 may require a different type of basic doping profile compared to one or more other device regions and hence a corresponding implantation sequence, for instance including the implantation process 240, may be performed on the basis of an implantation mask, such as the sacrificial material 204C, 204D (FIG. 2e) and the portion 204E. In other cases, the manufacturing process 240 may represent an etch process in which a corresponding material removal in the area covered by the portion 204E may not be desired. Consequently, due to the locally selective removal of sacrificial material, or at least a portion thereof, enhanced flexibility in designing an overall manufacturing process may be achieved, since portions of the sacrificial material may be repeatedly used, for instance as an implantation mask, an etch mask, a combination thereof and the like, thereby reducing the number of photolithography processes compared to conventional strategies. It should be appreciated that the process 240 may also include a further deposition process for depositing any appropriate material, such as resist material, polymer material and the like, possibly in combination with an associated photolithography process, wherein, at least in the area covered by the portion 204E, further enhanced material integrity may be accomplished.

FIG. 2g schematically illustrates the semiconductor device 200 according to further illustrative embodiments in which the selective removal of a “sacrificial material” may be applied to a metallization system 250 of the device 200. As illustrated, the metallization system 250 may comprise a dielectric material 252, for instance in the form of a low-k dielectric material, and a plurality of metal lines 251 embedded in the dielectric material 252. In sophisticated applications, the metal lines 251 may comprise a highly conductive metal, such as copper and the like, possibly in combination with other materials, such as conductive barrier materials and the like, in order to enhance overall performance of the metallization system 250. Furthermore, although sophisticated low-k dielectric materials may be used, which are to be understood as dielectric materials having a dielectric constant of 3.0 or less, nevertheless, the resulting parasitic capacitance between adjacent metal lines 251 may result in significant signal propagation delays and the like. Moreover, the usage of sophisticated low-k dielectric materials or ultra low-k dielectric materials may be associated with severe issues with respect to the mechanical and chemical integrity of these materials, thereby also contributing to a reduced reliability of the device 200 during operation and during further manufacturing processes for completing the device 200. For this reason, frequently, “air gaps” may be formed in critical device areas between adjacent metal lines 251, which in some approaches may be accomplished by etching the dielectric material 252 between the metal lines 251 on the basis of a non-masked selective etch recipe, during which material of the dielectric material 252 may be removed selectively to the metal lines 251. Although this approach may be advantageous in terms of avoiding complex lithography steps for defining the corresponding cavities between the metal lines 251, it may frequently be necessary to avoid the formation of air gaps in certain device regions, such as a device region 254, while in region 253 the corresponding air gaps may contribute to significant overall performance of the metallization system 250. In this case, an appropriate fill material, which may also be referred to as sacrificial material since at least a portion thereof may be removed, may be deposited, for instance, by spin-on techniques, chemical vapor deposition (CVD) and the like. For example, as illustrated in FIG. 2g, a corresponding material, also referred to as material 204, may thus fill respective cavities between the metal lines 251, wherein, if required, a planarization process may be performed, such as etching, chemical mechanical polishing (CMP) and the like, if desired. Thereafter, the energy 231 may be selectively applied to the device region 253 within the process ambient 230, thereby initiating evaporation of the exposed portion of the material 204, as previously explained. It should be appreciated that also in this case the characteristics of the material 204 may be appropriately selected so as to obtain the desired behavior upon deposition of energy therein compared to other materials, such as the metal lines 251 and the dielectric material 252. Furthermore, the characteristics of the material 204 may be selected such that it may be used for the further processing or may even represent a permanent material, i.e., the non-exposed portion of the material 204 in the device region 254 may act as an interlayer dielectric material of the device 200. For this purpose, a plurality of polymer materials are available, while in other cases a silicon-based material may be used. Consequently, after the evaporation of the material 204 in the device region 253, the resulting air gaps may be closed by depositing a further dielectric material thereon and the further processing may be continued by, for instance, forming a further metallization level of the system 250.

FIG. 3 schematically illustrates a material removal system 380 that is appropriately configured to remove material from a substrate on the basis of energy deposition and evaporation of the material, as previously explained. The system 380 may comprise a process chamber 381 that is appropriately configured to establish therein a low pressure process ambient, such as the process ambient 230 previously described with reference to FIGS. 2c and 2d. To this end, the process chamber 381 may comprise a supply system 386, which may be configured to introduce appropriate gaseous components, such as carrier gases, inert gases and the like, possibly in combination with additional reactive components, such as oxygen, hydrogen and the like, which may react with volatile components that are present in the process ambient 230 after evaporating a sacrificial material. It should be appreciated that reactive components in the form of radicals may also be supplied by the system 386, which may involve the preparation of corresponding radicals on the basis of remote plasma sources and the like. Moreover, the process chamber 381 may comprise an exhaust system 387, which may be configured to discharge gaseous components and any volatile process byproducts contained therein and also to maintain a desired process pressure, which may typically be selected to be below atmospheric pressure. For instance, the exhaust system 387 may comprise any pump system, as may typically be used in available deposition tools and the like. Moreover a substrate holder 383 may be positioned in the chamber 381 and may be appropriately configured to receive and hold in place a substrate, such as the substrate 201 as previously described. Furthermore, an energy source 382 may be provided so as to enable the deposition of energy in at least a portion of the material layer formed above the substrate 201. In the embodiment shown, the energy source 382 may be positioned within the process chamber 381, for instance in the form of a radiation source or a source of providing a beam of particles, as indicated by 382A. For example, in one illustrative embodiment, the energy source 382 may comprise a laser device that may provide an appropriate wavelength in combination with an appropriate intensity so as to obtain the desired power density for evaporating a sacrificial material formed above the substrate 201. As previously explained, a plurality of laser devices are available, such as tunable laser sources and the like, so that an appropriate wavelength may be readily selected in view of a built-in material to be treated on the basis of the beam 382A. In other cases, a laser source of fixed wavelength may be used in combination with other control mechanisms, such as a control of the spot size, intensity and the like. In other cases, the energy source 382 may comprise a flashlight source, which may provide high intensity radiation pulses with a moderately wide wavelength range, wherein pulse length, pulse repetition rate and the like, may be appropriately selected so as to obtain the desired degree of energy deposition. It should be appreciated that the energy source 382 may also be appropriately configured to perform an anneal process by appropriately selecting parameters for adjusting the beam 382A, if required. For instance, if moderately high temperatures may be considered advantageous for various device regions in and above the substrate 201, process parameters may be selected so as to obtain a desired surface temperature while at the same time efficiently evaporating any sacrificial material, the volatile components of which may then be efficiently removed from the process chamber 381 via the exhaust system 387. In the embodiment shown, the beam 382A provided by the energy source 382 may have a lateral size that may be significantly less compared to the diameter of the substrate 201. In this case, a scan system 384 may be operatively connected to the substrate holder 383 and/or the energy source 382 in order to establish a relative motion, indicated by 384A, between the substrate 201 and the beam 382A. To this end, the scan unit 384 may comprise any appropriate drive assembly, such as electric motors, piezoelectric actuators and the like, as may be required for achieving the relative motion 384A. Consequently, by applying an appropriate scan regime, the beam 382A may be directed in a spatially selective manner onto the substrate 201, thereby providing the possibility of selectively removing material with a spatial resolution that may be defined by the capability of the scan system 384 and the characteristics of the beam 382A. Furthermore, in the embodiment shown, a control unit 385 may be provided and may be operatively connected to the scan system 384 and the energy source 382. The control unit 385 may be configured to appropriately set up the energy source 382, for instance in view of obtaining a desired power density at selected areas of the substrate 201, which may be accomplished by controlling at least one of intensity, wavelength, exposure time and the like of the beam 382A generated by the energy source 382. Moreover, the control unit 385 may receive position information with respect to a sacrificial material to be removed from above the substrate 201 when, for instance, a portion thereof is to be maintained, as is also previously explained. In this case, the control unit 385 may provide appropriate control signals to the scan system 384 in order to control the relative motion 384A so as to obtain the desired patterning of a sacrificial material or avoiding the exposure of regions that are not covered by a sacrificial material, as is also previously described.

Thus, upon operating the system 380, an appropriate process ambient, such as the ambient 230, may be established after loading the substrate 201 into the process chamber 381 and onto the substrate holder 383. Next, the parameters of the beam 382A or of any other energy used for evaporating sacrificial material above the substrate 201 may be adjusted and, if required, a corresponding scan pattern may be applied in accordance with the overall process requirements. Upon energy deposition within a sacrificial material, as previously described, the volatile components thereof may be released into the process ambient 230 and may be further processed therein, for instance by a further decomposition initiated by additional reactive components, which may finally be removed via the exhaust system 387.

It should be appreciated that in other embodiments (not shown), the energy source 382, or at least a portion thereof, may be positioned outside the process chamber 381 and the energy may be coupled into the chamber 381 by any appropriate means, such as accelerator tubes when a particle beam is to be provided by beam-guiding systems and the like. Moreover, the energy may be applied so as to cover at least a significant portion of the substrate 201, thereby reducing the complexity of a corresponding scan system or avoiding the scan system when the energy may be supplied for the substrate 201 as a whole.

As a result, the present disclosure provides systems and techniques for removing a sacrificial material by evaporating the material, such as organic materials in the form of resist materials, polymer materials and the like, thereby reducing a negative effect on other materials of a semiconductor device. For example, resist material may be efficiently removed on the basis of evaporation, for instance caused by laser radiation, while suppressing interaction between remaining other materials and reactive components. During the evaporation process, volatile components are formed on the basis of energy deposited in the sacrificial material and these components may be further decomposed or may be removed from the process ambient, thereby reducing any further chemical interaction with other materials of the semiconductor device. In some illustrative embodiments, the removal process by evaporation may be accomplished in a locally selective manner, thereby providing the possibility of selectively exposing device regions. For instance, only portions of a specific material may be removed, while other portions may be maintained during one or more further process steps or may represent permanent material portions of the semiconductor device under consideration. Hence, a plurality of material removal processes, such as resist strip processes, may be performed on the basis of evaporation without unduly affecting other device regions, thereby significantly improving reliability and performance of sophisticated semiconductor devices.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of removing a sacrificial material from above a surface of a semiconductor device, the method comprising:
transferring energy into at least a portion of said sacrificial material within a process ambient so as to evaporate said at least a portion of said sacrificial material and release volatile components of said sacrificial material into said process ambient; and
processing said volatile components in said process ambient.

2. The method of claim 1, wherein said sacrificial material comprises a photochemically sensitive material.

3. The method of claim 2, wherein said sacrificial material comprises a resist material.

4. The method of claim 1, wherein transferring energy into at least a portion of said sacrificial material comprises exposing said at least a portion of said sacrificial material to a beam of at least one of radiation and particles.

5. The method of claim 4, wherein transferring energy into said at least a portion of said sacrificial material comprises exposing said at least a portion to a laser beam.

6. The method of claim 4, wherein transferring energy into at least a portion of said sacrificial material comprises selectively exposing a first device region to said beam so as to remove said at least a portion while substantially avoiding exposure to said beam in a second device region of said semiconductor device so as to maintain a second portion of said sacrificial material.

7. The method of claim 6, further comprising performing a manufacturing process on said semiconductor device by using at least said second portion as a process mask.

8. The method of claim 7, wherein performing said manufacturing process comprises performing at least one of an implantation process and an etch process.

9. The method of claim 1, wherein processing said volatile components comprises supplying a reactive species to said process ambient so as to initiate a chemical reaction with said volatile components of said sacrificial material.

10. The method of claim 1, wherein transferring energy into at least a portion of said sacrificial material comprises annealing at least a surface region of said semiconductor device.

11. The method of claim 10, wherein annealing at least a surface region of said semiconductor device comprises annealing an entire surface of said semiconductor device.

12. The method of claim 10, wherein annealing at least a surface region comprises selectively annealing said surface region in a first device region.

13. The method of claim 1, wherein processing said volatile components in said process ambient comprises removing said volatile components from said process ambient.

14. A method, comprising:
performing a process on a semiconductor device by using an organic material as a mask; and
exposing at least a portion of said organic material to at least one of radiation and energetic particles so as to evaporate said at least a portion of said organic material.

15. The method of claim 14, further comprising suppressing exposure of a second portion of said organic material to said at least one of radiation and energetic particles.

16. The method of claim 14, wherein exposing said at least a portion to at least one of radiation and energetic particles comprises exposing said at least a portion to electromagnetic radiation.

17. The method of claim 16, wherein exposing said at least a portion to electromagnetic radiation comprises exposing said at least a portion to at least one of a laser beam and a flash light irradiation.

18. The method of claim 16, wherein exposing said at least a portion to electromagnetic radiation comprises exposing said at least a portion to microwave radiation.

19. The method of claim 14, further comprising supplying a reactive species so as to initiate a chemical reaction between evaporated components of said organic material and said reactive species.

20. A material removal system, comprising:
a process chamber configured to establish a specified low-pressure process ambient;
a substrate holder positioned in said process chamber and configured to receive and hold in place a substrate having formed thereon semiconductor devices and a material to be removed from said semiconductor devices; and
an energy source positioned so as to transfer energy into said material and to evaporate said material.

21. The material removal system of claim 20, wherein said energy source comprises a beam generator configured to provide a beam of at least one of radiation and energetic particles.

22. The material removal system of claim 21, further comprising a scan unit operatively connected to at least one of said energy source and said substrate holder and configured to establish a relative motion between said beam and said substrate holder.

23. The material removal system of claim 22, wherein said scan unit is further configured to receive position information and to control said relative motion so as to maintain a portion of said material.

24. The material removal system of claim 20, wherein said energy source is configured to evaporate a resist material.

25. The material removal system of claim 21, wherein said beam generator comprises a laser device.
